(19) United States
(12) Patent Application Publication
(10) Pub. No.: US 2007/0164355 A1
(43) Pub. Date: Jul. 19, 2007

(54) Semiconductor device of high breakdown voltage and manufacturing method thereof

(76) Inventor: Tae-Pok Rhee, Suwon-si (KR)

Correspondence Address: IPLA P.A., 3580 WILSHIRE BLVD., 17TH FLOOR, LOS ANGELES, CA, 90010, US

(21) Appl. No.: 10/598,495

(22) PCT Filed: Mar. 2, 2005
(86) PCT No.: PCT/KR05/00574

§ 371 Date: Aug. 31, 2006

(30) Foreign Application Priority Data
Mar. 2, 2004 (KR) 10-2004-0014036

(51) Int. Cl. H01L 29/76

(52) U.S. Cl. 257/339

(57) ABSTRACT

Disclosed are a semiconductor device of high breakdown voltage and a method manufacturing the same. According to the invention, it is possible to previously prevent an increase size of the device due to a separation of a high concentration impurity layer and a gate electrode pattern by embedding the gate electrode pattern in a bottom of a semiconductor substrate, and sequentially stacking a low concentration impurity layer and a high concentration impurity layer for source/drain diffusion layers on both sides of the gate electrode pattern, thereby allowing the high concentration impurity layer to easily secure a voltage drop areas necessary for itself without being spaced from the gate electrode pattern.

### TECHNICAL FIELD

The present invention relates to a semiconductor device of high breakdown voltage. In the present invention, the gate electrode pattern is embedded in a bottom of a semiconductor substrate, and low concentration impurity layers and high concentration impurity layers for source/drain diffusion layers are sequentially stacked on both sides of the gate electrode pattern. Thus, the high concentration impurity layer may easily secure a voltage drop area necessary for itself without being spaced from the gate electrode pattern. Thus, more specifically, the present invention relates to a semiconductor device of high breakdown voltage capable of previously preventing a size increase of the device which results from a separation of a high concentration impurity layer and a gate electrode pattern. In addition, the present invention relates to a manufacturing method of such a semiconductor device of high breakdown voltage.

### BACKGROUND ART

In recent years, as various kinds of electronics such as a liquid crystal display and a plasma display panel are developed and popularized, a demand for a semiconductor device of high breakdown voltage which may be connected to and operate various peripheral devices equipped to such electronics is also rapidly increasing.

As shown in FIG. 1, in a semiconductor device of high breakdown voltage according to the prior art, a semiconductor substrate 1 is separated into a device separating area and an active area by a device separating film 2. The active area of the semiconductor substrate 1 is provided with a gate electrode pattern 10, a gate insulating layer pattern 9 and source/drain diffusion layers 8,5, etc. The source/drain diffusion layers 8,5 comprise high concentration impurity layers 7,4 and low concentration impurity layers 6,3, etc., which are combined with each other.

With the semiconductor device of high breakdown voltage according to the prior art, as shown in FIG. 1, the high concentration impurity layers 7,4 of the source/drain diffusion layers 8,5 are spaced at an interval (L) from both sides of the gate electrode pattern 10 to secure a voltage drop area beyond a certain level.

Of course, when the high concentration impurity layers 7, 4 of the source/drain diffusion layers 8,5 does not maintain a certain distance spaced from the gate electrode pattern 10, a normal area of voltage drop is not secured. Accordingly, a serious problem occurs, for example, outer lines of the low concentration impurity layers 6,3 are broken due to a high voltage applied from an exterior before they reach an operating voltage.

Under such structure, a voltage drop of the device occurs in the direction from the high concentration impurity layers 7,4 to the low concentration impurity layers 6,3. That is to say, it occurs in the horizontal direction along a surface of the semiconductor substrate 1, which is similar to the direction of a channel. This is because a curved portion to which a magnetic field is highest applied is firstly broken when a depth of the low concentration impurity layer is somewhat secured.

When the high concentration impurity layers 7,4 of the source/drain diffusion layers 8,5 are spaced at the interval (L) from both sides of the gate electrode pattern 10 as mentioned above, it is possible to obtain an advantage of securing a voltage drop area beyond a certain level. However, a manufacturer may have serious problems that the size of the finally completed semiconductor device of high breakdown voltage sharply increases in proportion to the spaced distance of the high concentration impurity layers 7,4, and that, thus, the cost for manufacturing the device rises sharply.

### DISCLOSURE OF INVENTION

Accordingly, the present invention has been made to solve the above-mentioned problems occurring in the prior art. The object of the present invention is to previously prevent a size increase of a semiconductor device of high breakdown voltage which results from a separation of a high concentration impurity layer and a gate electrode pattern. It can be accomplished by embedding the gate electrode pattern in a bottom of a semiconductor substrate, and sequentially stacking low concentration impurity layers and high concentration impurity layers for source/drain diffusion layers on both sides of the gate electrode pattern, thereby allowing the high concentration impurity layers to easily secure a voltage drop areas necessary for itself without being spaced from the gate electrode pattern.

Another object of the invention is to improve a form of a gate electrode pattern and source/drain diffusion layers, thereby achieving a size minimization of the device and thus drastically reducing the manufacturing cost of the device finally obtained.

In order to accomplish the object, there is provided a semiconductor device of high breakdown voltage. The semiconductor device of high breakdown voltage comprising: a gate electrode pattern embedded in an active area of a semiconductor substrate, which area is defined by a device separating film having an inversion preventing layer; a gate insulating layer pattern surrounding the gate electrode pattern; high concentration impurity layers located on both sides of the gate electrode pattern to contact the gate insulating layer pattern and formed in an upper layer of the active area of the semiconductor substrate by an ion implantation; and low concentration impurity layers located on both sides of the gate electrode pattern to contact the gate insulating layer pattern and formed under the high concentration impurity layers by the ion implantation.

Another aspect of the invention, there is provided a method of manufacturing the semiconductor device of high breakdown voltage. The method comprising steps of: forming a trench in an active area of a semiconductor substrate; forming a gate insulating layer pattern on a surface of the trench; forming a gate electrode pattern in the trench to contact the gate insulating layer pattern; forming low concentration impurity layers in the active area of the semiconductor substrate to contact the gate insulating layer pattern and to be located on both sides of the gate electrode pattern by ion implantation; and forming high concentration impurity layers on the low concentration impurity layers to contact the gate insulating layer pattern and to be located on both sides of the gate electrode pattern by ion implantation.

### BRIEF DESCRIPTION OF DRAWINGS

The above and other objects, features and advantages of the present invention will be more apparent from the following detailed description taken in conjunction with the accompanying drawings, in which:

FIG. 1 is an exemplary view showing a semiconductor device of high breakdown voltage according to the prior art;

FIG. 2 is an exemplary view showing a semiconductor device of high breakdown voltage according to the present invention;

FIGS. 3 to 9 are views sequentially showing a method of manufacturing a semiconductor device of high breakdown voltage according to the present invention.

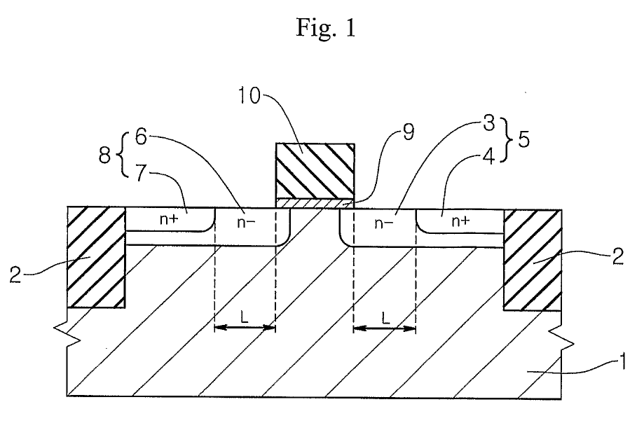

### BEST MODE FOR CARRYING OUT THE INVENTION

Hereinafter, preferred embodiments of the present invention will be described with reference to the accompanying drawings. In the following description of the present invention, a detailed description of known functions and configurations incorporated herein will be omitted when it may make the subject matter of the present invention rather unclear.

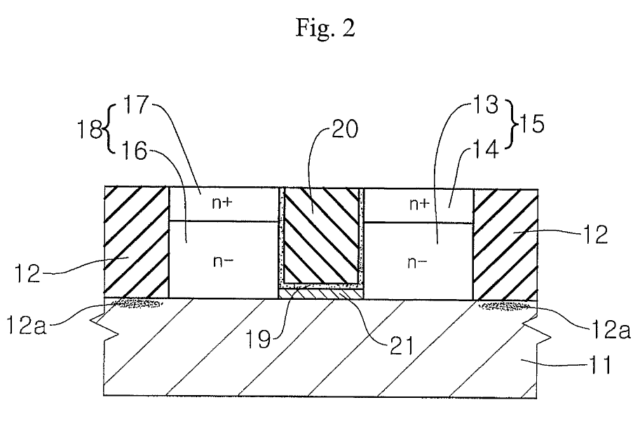

As shown in FIG. 2, a semiconductor device of high breakdown voltage according to the invention comprises a gate electrode pattern 20 embedded in an active area of a semiconductor substrate 11, which area is defined by a device separating film 12, a gate insulating layer pattern 19 surrounding edges of the gate electrode pattern 20, and high concentration impurity Layers 17,14 and low concentration impurity layers 16,13 located at both sides of the gate electrode pattern 20 to contact the gate insulating layer pattern 19 and constituting source/drain diffusion layers 18,15. Are inversion preventing layer 12a for improving a device separating function of the device separating film 12a may be further formed in a bottom of the device separating film 12.

The gate insulating layer pattern 19 forms a horizontal channel from the source diffusion layer 18 to the drain diffusion layer 15 as the gate electrode pattern 20 is operated. Preferably, a threshold voltage control layer 21 for controlling a threshold voltage of the channel formed by the gate insulating layer pattern 19 is further formed in a bottom of the gate insulating layer pattern 19.

The gate electrode pattern 20 is preferably embedded in a depth shallower than the device separating film 12, and maintains a width generally wider than the device separating film 12.

As shown in FIG. 2, the high concentration impurity layers 17,14 have a structure formed on an upper layer of the active area of the semiconductor substrate 11 by ion implantation. The low concentration impurity layers 16,13 have a structure formed under the high concentration impurity layer 17,14 by ion implantation. In other words, according to the invention, the high concentration impurity layers 17,14 and the low concentration impurity layers 16,13 form a structure such that they are sequentially stacked.

Of course, the reason why the high concentration impurity layers 17,14 and the low concentration impurity layers 16,13 can form the stacked structure without particular problems is that the gate electrode pattern 20 is embedded in the bottom of the semiconductor substrate 11 contrary to the prior art.

According to the prior art, the high concentration impurity layers of the source/drain diffusion layers are spaced at an interval (L) from both sides of the gate electrode pattern in order to secure voltage drop areas beyond a certain level. Under such structure, the voltage drop of the device occurs in the direction from the high concentration impurity layer to the low concentration impurity layer. That is to say, it occurs in the horizontal direction along a surface of the semiconductor substrate, similarly to the channel direction. Thus, the size of the device finally obtained is inevitably drastically increased in proportion to a spaced distance of the high concentration impurity layer.

However, according to the invention, since the high concentration impurity layers 17,14 and the low concentration impurity layers 16,13 form a sequentially stacked structure in which they are located up and down, the voltage drop of the device occurs in the direction from high concentration impurity layers 17,14 to low concentration impurity layers 16,13. That is to say, it occurs in the vertical direction toward the bottom of the semiconductor device 11, differently from the channel direction. Accordingly, the high concentration impurity layers 17,14 can easily secure a voltage drop areas necessary for itself without being spaced from the gate electrode pattern 20.

Of course, when the need of spacing the high concentration impurity layers 17,14 and the gate electrode pattern 20 is effectively excluded according to the invention, a size of a device finally obtained is drastically decreased and the problem of the rise in the manufacturing cost due to the increased size of the device is thus naturally solved.

A positional relationship between the inversion preventing layer 12a of the device separating film 12 and the high concentration impurity layers 17,14 may act as a very important factor in embodying the invention. If the inversion preventing layer 12a of the device separating film 12 and the high concentration impurity layers 17,14 contact each other, a range of high breakdown voltage within which the high concentration impurity layers 17,14 can withstand may be highly decreased.

According to the invention, considering the above problem, the inversion preventing layer 12a of the device separating film 12 and the high concentration impurity layers 17,14 are completely separated so as not to electrically contact each other. Thus, it is possible to previously prevent the range of high breakdown voltage from being reduced.

In addition, a relationship between an embedded depth of the gate electrode pattern 20 and junction depths of the low concentration impurity layers 16,13 may act as a very important factor in embodying the invention. If the junction depths of the low concentration impurity layers 16,13 are shallower than the embedded depth of the gate electrode pattern 20, the contacts of the gate insulating layer pattern 19 and the low concentration impurity layers 16,13 are not smoothly made, so that a channel may not be normally formed.

According to the invention, considering the above problem, the junction depth of the low concentration impurity layers 16,13, for example, a junction depth after a drive-in process which will be described later is made to be equal to or deeper than the depth of the embedded gate electrode pattern 20, in order to ensure a smooth formation of the channel in advance.

Hereinafter, a method of manufacturing the semiconductor device of high breakdown voltage having the above described structure will be specifically explained.

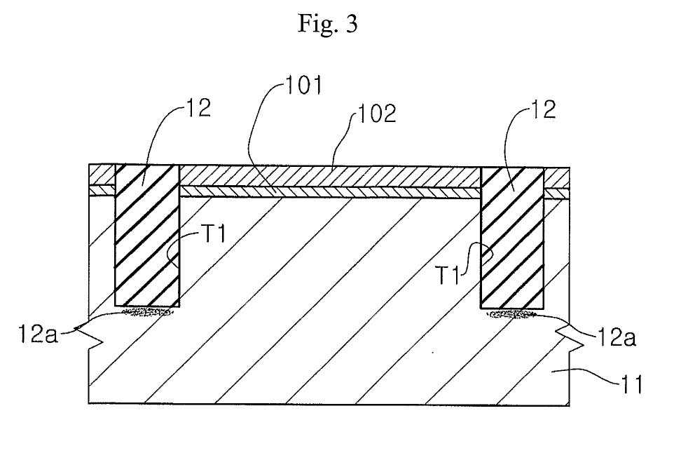

As shown in FIG. 3, according to the invention, a pad oxide layer 101 having a thickness of, for example, 200 Å˜500 Å is grown on a front surface of the semiconductor substrate 11 such as a single crystal silicon through a high temperature thermal oxidation process.

Then, a silicon nitride layer 102 having a thickness of, for example, 1000 Å˜2000 Å is formed on the pad oxide layer 101 through a low pressure chemical vapor deposition process.

After that, a photoresist pattern (not shown) is formed on the silicon nitride layer 102 so that an opening of the photoresist film is located in the device separating area of the semiconductor substrate 11. Then, the pad oxide layer 101 and the silicon nitride layer 102 are patterned so that the device separating area of the semiconductor substrate 11 is exposed through a dry etching processes having an anisotropic characteristic (e.g., a reactive ion etching process) using the photoresist pattern as an etch mask.

Subsequently, the device separating area, which is already exposed, of the semiconductor substrate 11 is anisotropically etched in a depth of about 10000A through the reactive ion etching process using the photoresist pattern as the etch mask layer so that a device separating trench (T1) is formed in the device separating area of the semiconductor substrate 11.

When the formations of the device separating trenches (T1) are completed through the above processes, the inversion preventing layers 12a are selectively further formed in the bottom of the device separating trenches (T1) through an ion implantation processes. After that, an oxide layer (not shown) having a thickness of, for example, 400 Å˜600 Å is formed on a surface of the device separating trench (T1) through a thermal oxidation process at 900° C.˜1100°, for example.

Subsequently, according to conditions, for example, an O₃-tetra ortho silicate glass (TEOS) process, an atmospheric pressure chemical vapor deposition process, a plasma chemical vapor deposition process, and a high density plasma chemical vapor deposition (HDP CVD) process are selectively performed, thereby forming the device separating film 12 having, for example, an oxide layer material in the device separating trench (T1).

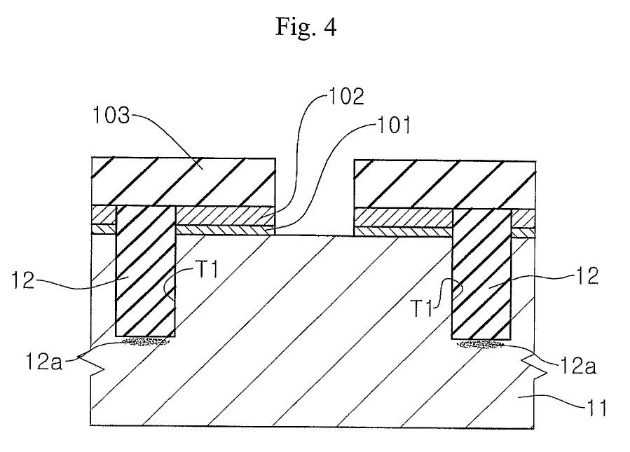

Referring to FIG. 4, when the Formation of the device separating film 12 is completed through the above processes, a photoresist pattern 103 is formed on the silicon nitride layer 102 so that an opening of the photoresist film is located in the active area of the semiconductor substrate 11. Then, the pad oxide layer 101 and the silicon nitride layer 102 are patterned so that the active area of the semiconductor substrate 11 is exposed through a dry etching processes having an anisotropic characteristic(e.g., a reactive ion etching process) using the photoresist pattern 103 as an etch mask.

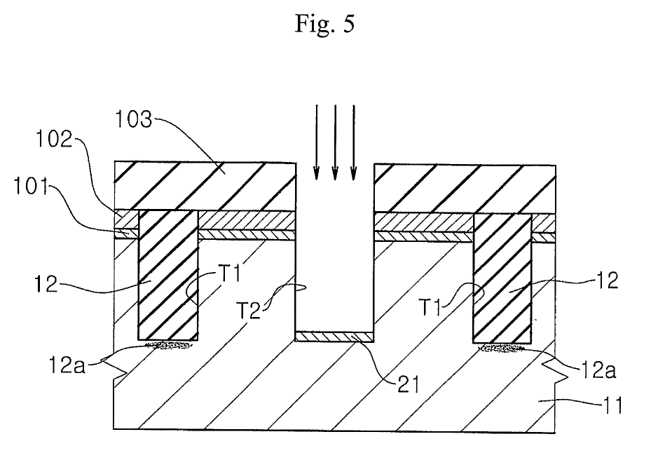

Subsequently, as shown in FIG. 5, the active area, which is already exposed, of the semiconductor substrate 11 is anisotropically etched in a depth of about 3000 Å˜9800 Å through the reactive ion etching process using the photoresist pattern 103 as the etch mask layer so that a trench (T2) for the gate electrode is formed in the active area of the semiconductor substrate 11.

Then, an ion implantation process targeting a bottom surface of the trench (T2) for the gate electrode is performed so that threshold voltage control layers 21 are formed in the bottom of the trench (T2) for the gate electrode. After that, the photoresist pattern 103 is removed.

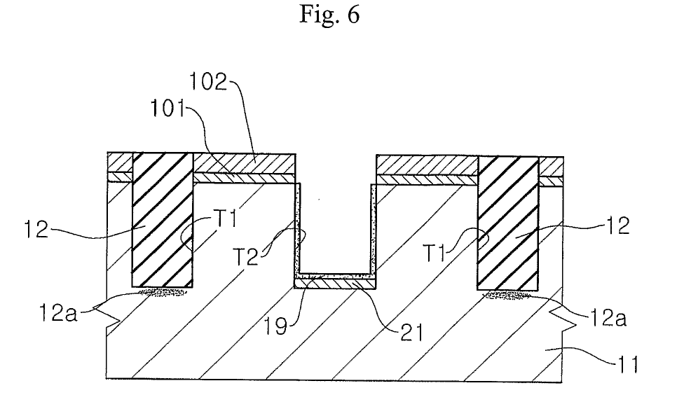

Subsequently, as shown in FIG. 6, the gate insulating layer pattern 19 having a thickness of, preferably, 180 Å˜2500 Å is grown and formed on a surface of the trench (T2) for the gate electrode through a thermal oxidation process at 850° C.˜1100°, for example.

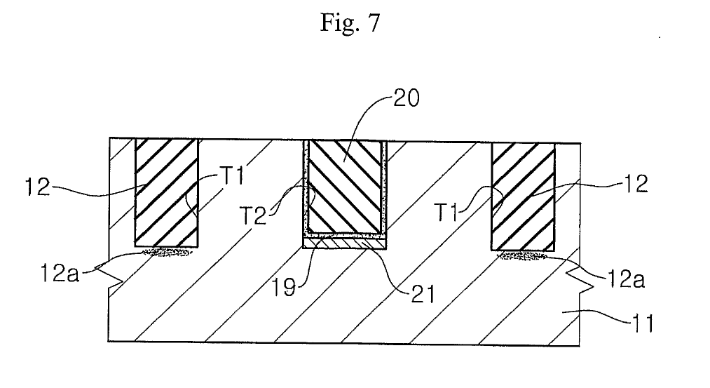

Then, as shown in FIG. 7, deposition processes are selectively performed so that the gate electrode pattern 20, which comprises for example, polysilicon doped in high concentration and contacts the gate insulating layer pattern 19, is formed in the trench (T2) for the gate electrode.

Subsequently, a wet etching process using phosphoric acid, hydrofluoric acid solutions, etc. is performed so that the silicon nitride layer 102 and the pad oxide layer 101 are removed from the surface of the semiconductor substrate 11.

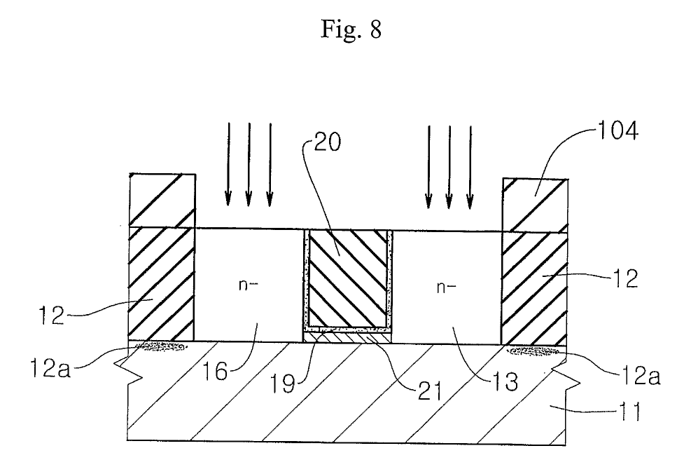

When the formation of the gate insulating layer pattern 19 embedded in the form of the trench in the active area of the semiconductor substrate 11 is completed through the above described processes, as shown in FIG. 8, a photoresist pattern 104 is formed on the semiconductor substrate 11 so that the opening of the photoresist film is located in the active area of the semiconductor substrate 11. Then, an ion implantation process using the photoresist pattern 104 as the mask is performed so that the low concentration impurity layers 16,13 contacting the gate insulating layer pattern 19 and located on both sides of the gate electrode pattern 20 are formed. After that, the photoresist pattern 104 is removed.

Subsequently, a drive-in process is performed at a predetermined high temperature, preferably 1000° C.˜1250° C. for 30 min.˜600 min. so as to increase a voltage drop capability of the low concentration impurity layers 16,13.

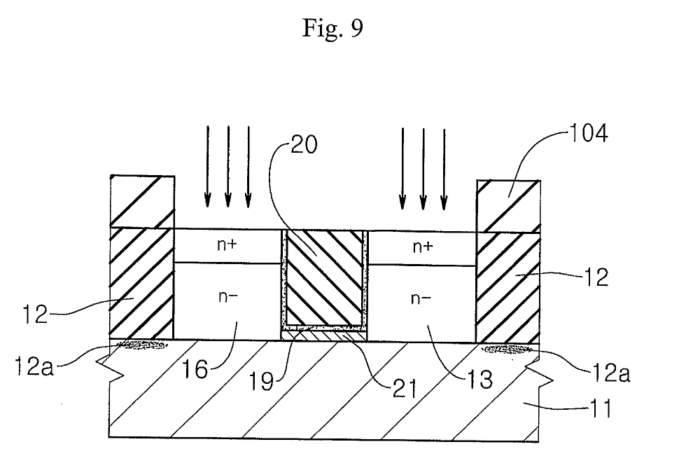

After the completion of the above drive-in process, as shown in FIG. 9, a photoresist pattern 104 is formed on the semiconductor substrate 11 so that the opening of the photoresist film 11 is located in the active area of the semiconductor substrate 11. Then, an ion implantation process using the photoresist patterns 104 as the mask is performed so that the high concentration impurity layers 17,14 located on both sides of the gate electrode pattern 20 and located on the low concentration impurity layers 16,13 are formed. After that, the photoresist pattern 104 is removed.

After that, a process for forming an insulation layer, a contact hole, a metal wiring, etc. are further repeatedly performed, thereby completing the manufacture of the semiconductor device of high breakdown voltage.

### INDUSTRIAL APPLICABILITY

As described above, according to the invention, the gate electrode pattern is embedded in the bottom of the semiconductor substrate and the low concentration impurity layers and the high concentration impurity layers for the source/drain diffusion layers are sequentially stacked on both sides of the gate electrode pattern, thereby allowing the high concentration impurity layers to easily secure a voltage crop areas necessary for itself without being spaced from the gate electrode pattern. Accordingly, it is possible to prevent the size increase of the device due to the separation of the high concentration impurity layers and the gate electrode pattern in advance.

When the need of spacing the high concentration impurity layers and the gate electrode pattern is effectively excluded according to the invention, a size of the device finally completed is drastically reduced and it is thus possible to solve the problem of a rise in manufacturing cost due to the size increase of the device.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A semiconductor device of high breakdown voltage comprising:
a gate electrode pattern embedded in an active area of a semiconductor substrate, which area is defined by a device separating film having an inversion preventing layer;
a gate insulating layer pattern surrounding the gate electrode pattern;
high concentration impurity layers located on both sides of the gate electrode pattern to contact the gate insulating layer pattern and formed in an upper layer of the active area of the semiconductor substrate by an ion implantation; and
low concentration impurity layers located on both sides of the gate electrode pattern to contact the gate insulating layer pattern and formed under the high concentration impurity layers by an ion implantation.

2. The device according to claim 1, wherein the high concentration impurity layers are separately formed so as not to electrically contact the inversion preventing layer of the device separating film.

3. The device according to claim 1, wherein junctions of the low concentration impurity layers are formed at a depth equal to or deeper than the depth of the embedded gate electrode pattern by the ion-implantation.

4. The device according to claim 1, wherein the gate electrode pattern is embedded in a depth shallower than the device separating film.

5. The device according to claim 1, wherein the gate electrode pattern maintains a width wider than the device separating film.

6. The device according to claim 1, further comprising a threshold voltage control layer provided in a bottom of the gate insulating layer pattern for controlling a threshold voltage of a channel formed by the gate insulating layer pattern.

7. A method of manufacturing a semiconductor device of high breakdown voltage comprising steps of:
forming a trench in an active area of a semiconductor substrate;
forming a gate insulating layer pattern on a surface of the trench;
forming a gate electrode pattern in the trench to contact the gate insulating layer pattern;
forming low concentration impurity layers in the active area of the semiconductor substrate to contact the gate insulating layer pattern and to be located on both sides of the gate electrode pattern by an ion implantation; and
forming high concentration impurity layers on the low concentration impurity layers to contact the gate insulating layer pattern and to be located on both sides of the gate electrode pattern by an ion implantation.

8. The method according to claim 7, further comprising a step of forming a threshold voltage control layer in a bottom of the gate insulating layer pattern for controlling a threshold voltage of a channel formed by the gate insulating layer pattern.

9. The method according to claim 7, wherein the gate insulating layer pattern is formed to have a thickness of 180 Å˜2500 Å.

10. The method according to claim 7, further comprising a step of driving-in the low concentration impurity layers at high temperatures.

11. The method according to claim 10, wherein the step of driving-in the low concentration impurity layers is performed at 1000° C.˜1250° C.

12. The method according to claim 10, wherein the step of driving-in the low concentration impurity layers is performed for 30 min.˜600 min.
